(19) United States
(12) Patent Application Publication
(10) Pub. No.: US 2016/0095254 A1
(43) Pub. Date: Mar. 31, 2016

(54) MANAGING HEAT TRANSFER FOR ELECTRONIC DEVICES

(71) Applicant: International Business Machines Corporation, Armonk, NY (US)

(72) Inventors: Phillip V. Mann, Rochester, MN (US); Kevin M. O'Connell, Rochester, MN (US); Arvind K. Sinha, Rochester, MN (US); Karl Stathakis, Rochester, MN (US)

(21) Appl. No.: 14/499,318

(22) Filed: Sep. 29, 2014

(51) Int. Cl. H05K 7/20; B23P 15/26

(52) U.S. Cl. CPC H05K 7/20336; H05K 7/20318; H05K 7/20309; H05K 7/20327; B23P 15/26; B23P 2700/09

(57) ABSTRACT

An apparatus for cooling a heat-producing electronic device is disclosed. The apparatus may include a thermally conductive vessel to mate with and contain a working fluid in contact with the heat-producing electronic device. A bottom side of the thermally conductive vessel may include a sealing surface defining an aperture and configured to mate with, and inside a perimeter of, a top surface of the heat-producing electronic device. The thermally conductive vessel may also include an evaporative cavity formed by mating the thermally conductive vessel with the heat-producing electronic device, and having a wall that is the top surface of the heat-producing electronic device and a wall that is an interior surface of the thermally conductive vessel. The thermally conductive vessel may also include a condensing cavity adjoining the evaporative cavity, to receive heat by condensing the working fluid from a vapor state to a liquid state.

### BACKGROUND

The present disclosure generally relates to transferring heat generated by electronic devices. In particular, this disclosure relates to using a heat pipe apparatus having an efficient thermal interface to remove heat from an electronic device.

A heat pipe may be used in computers and other electronic systems as a heat-transfer device that combines the principles of both thermal conductivity and phase transition to efficiently transfer heat between an electronic device and a heat-dissipating device. Heat pipes may be used in computers, for example, to transfer heat from devices such as central processing units (CPUs) and/or graphics processing units (GPUs) to heat-dissipating devices such as heat sinks or radiating fins. A heat pipe device may include a sealed pipe or tube containing a working fluid such as water or ammonia. The working fluid may transfer heat by being vaporized in a section of the pipe thermally coupled to a heat source, the vapor subsequently flowing to and being condensed in another section of the pipe thermally connected to a heat sink.

A thermal interface material (TIM) may be used to enhance heat transfer between an electronic device, such as an integrated circuit (IC), and a heat sink, and may be fabricated from thermally conductive material. A TIM may enhance thermal conductivity by replacing irregularities and air gaps between adjacent, mating surfaces (e.g., of the IC and the heat sink) with a thermally conductive material.

### SUMMARY

Various aspects of the present disclosure may be useful for enabling efficient heat transfer from a heat-producing electronic device. A heat pipe apparatus configured according to embodiments of the present disclosure may limit the operating temperature and increase the reliability of a heat-producing electronic device.

Embodiments may be directed towards an apparatus for cooling a heat-producing electronic device. The apparatus may include a thermally conductive vessel, configured to, when mated with the heat-producing electronic device, contain a working fluid in contact with the heat-producing electronic device. The thermally conductive vessel may have a sealing surface, on a bottom side of the thermally conductive vessel, that defines an aperture and that is configured to mate with, and inside a perimeter of, a top surface of the heat-producing electronic device. The thermally conductive vessel may also have an evaporative cavity formed by mating the thermally conductive vessel with the heat-producing electronic device, and having a first wall that is the top surface of the heat-producing electronic device and a second wall that is an interior surface of the thermally conductive vessel. The thermally conductive vessel may also have at least one condensing cavity adjoining the evaporative cavity and configured to, when the thermally conductive vessel is mated to the heat-producing electronic device, receive heat from the working fluid by condensing the working fluid from a vapor state to a liquid state.

Embodiments may also be directed towards a method for assembling a heat pipe apparatus for cooling a heat-producing electronic device. The method may include aligning a sealing surface on a bottom side of a thermally conductive vessel within a perimeter of a top surface of the heat-producing electronic device. The method may also include creating, by mating the sealing surface of the thermally conductive vessel with the top surface of the heat-producing electronic device, an evaporative cavity having a first wall that is the top surface of a heat-producing electronic device and a second wall that is an interior surface of the thermally conductive vessel. The method may also include sealing, by exerting a force normal to the top surface of the heat-producing electronic device to hold the thermally conductive vessel to the heat-producing electronic device, the evaporative cavity and introducing, into the evaporative cavity, a quantity of working fluid to be in contact with and to cool, by receiving heat from, the top surface of the heat-producing electronic device.

Embodiments may also be directed towards a method for operating a heat pipe apparatus to remove heat from a heat-producing electronic device. The method may include vaporizing, using dissipated heat from the heat-producing electronic device, a portion of a working fluid contained within an evaporative cavity having a first wall that is a top surface of the heat-producing electronic device and a second wall that is an interior surface of a thermally conductive vessel. The method may also include flowing, in response to a vapor pressure differential between the evaporative cavity and a condensing cavity, a portion of vaporized working fluid to at least one condensing cavity of the thermally conductive vessel. The method may also include condensing, onto a surface of the condensing cavity, at least a portion of the vaporized working fluid, to transfer at least a portion of the dissipated heat to the condensing cavity and to form working fluid condensate. The method may also include flowing the working fluid condensate from the condensing cavity to the evaporative cavity of the thermally conductive vessel.

Aspects of the various embodiments may be used to enhance the maximum performance of, and power that may be dissipated from, a heat-producing electronic device. Aspects of the various embodiments may also be useful for providing a cost-effective, compact and lightweight heat pipe apparatus and interface for use with heat-producing electronic components by using existing and proven materials, thermodynamic processes and mechanical design, simulation, machining and fabrication technologies.

The above summary is not intended to describe each illustrated embodiment or every implementation of the present disclosure.

### BRIEF DESCRIPTION OF THE DRAWINGS

The drawings included in the present application are incorporated into, and form part of, the specification. They illustrate embodiments of the present disclosure and, along with the description, serve to explain the principles of the disclosure. The drawings are only illustrative of certain embodiments and do not limit the disclosure.

FIG. 1 includes four cross-sectional drawings depicting an apparatus for cooling a heat-producing electronic device, according to embodiments of the present disclosure.

FIG. 2 is a cross-sectional drawing depicting an apparatus for cooling a heat-producing integrated circuit die, according to embodiments consistent with FIG. 1.

FIG. 3 depicts a sequence of steps for assembling a heat pipe apparatus, according to embodiments consistent with the figures.

FIG. 4 depicts the operation of a heat pipe apparatus, according to embodiments consistent with the figures.

FIG. 5 is a flow diagram of a method of assembling a heat pipe apparatus, according to embodiments consistent with the figures.

FIG. 6 is a flow diagram of a method for operating a heat pipe apparatus, according to embodiments consistent with the figures.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention.

In the drawings and the Detailed Description, like numbers generally refer to like components, parts, steps, and processes.

### DETAILED DESCRIPTION

Certain embodiments of the present disclosure can be appreciated in the context of providing efficient heat transfer from electronic devices located within rack-mounted equipment such as servers, network switching systems and telecommunications equipment. Such rack-mounted equipment may be used to provide data to clients attached to a server through a network and/or provide switching and communications functions for data and telecommunications networks. While not necessarily limited thereto, embodiments discussed in this context can facilitate an understanding of various aspects of the disclosure. Certain embodiments may also be directed towards other equipment and associated applications, such as providing enhanced heat transfer from electronic devices located within desktop personal computers, which may be used in a wide variety of computational and data processing applications. Such desktop personal computers may include a variety of configurations and workstation types. Embodiments may also be directed towards providing enhanced heat transfer from electronic devices located within mobile devices such as cell phones, pagers and personal digital assistants (PDAs), to limit the operating temperature of the electronic devices.

For ease of discussion, the terms “copper” and “aluminum” are used herein, however, it is understood that various embodiments can also be useful with regards to metallic alloys which may include copper and/or aluminum.

A heat-producing electronic device such as an integrated circuit (IC) or other electronic module or assembly may be cooled by thermally dissipative devices (e.g., heat sink) to limit the device's operating temperature. Limiting a heat-producing electronic device's operating temperature to a specified range may allow it to operate reliably for the duration of a specified operating life.

In certain applications however, for example where space or cooling airflow in the vicinity of a heat-producing electronic device is limited, a heat sink may not be sufficient to effectively limit the device's operating temperature within a specified range. In these applications, a heat pipe device may be useful for the removal or transfer of heat from the heat producing electronic device.

A thermal interface between heat-producing electronic device and working fluid within a heat pipe may include several layers, e.g., a thermal interface material (TIM), a heat sink base, a solder layer and a heat pipe wall. Each interface each layer may offer thermal resistance to heat flow from the heat-producing electronic device to the heat pipe, which in turn may limit heat removal and the maximum power and performance of the electronic device.

According to embodiments of the present disclosure, a heat pipe apparatus may contains a working fluid in direct contact with a heat-producing electronic device, which may be useful in efficiently transferring heat from the heat-producing electronic device to a remote location. In certain embodiments, efficient heat transfer from an electronic device can be useful for providing a desired device operating temperature range and increased electronic device and system reliability. In certain embodiments, efficient heat transfer from an electronic device may allow the device to dissipate an increased amount of heat, which may allow the device to be operated at a higher frequency and yield higher device and/or system performance, relative to a device having less efficient heat transfer. A heat pipe apparatus according to embodiments may be installed using an assembly process that is simplified relative to an assembly process for other types of heat pipe apparatus assemblies. A heat pipe apparatus according to embodiments may be cost-effective, smaller and lighter than other types of heat pipe apparatus assemblies.

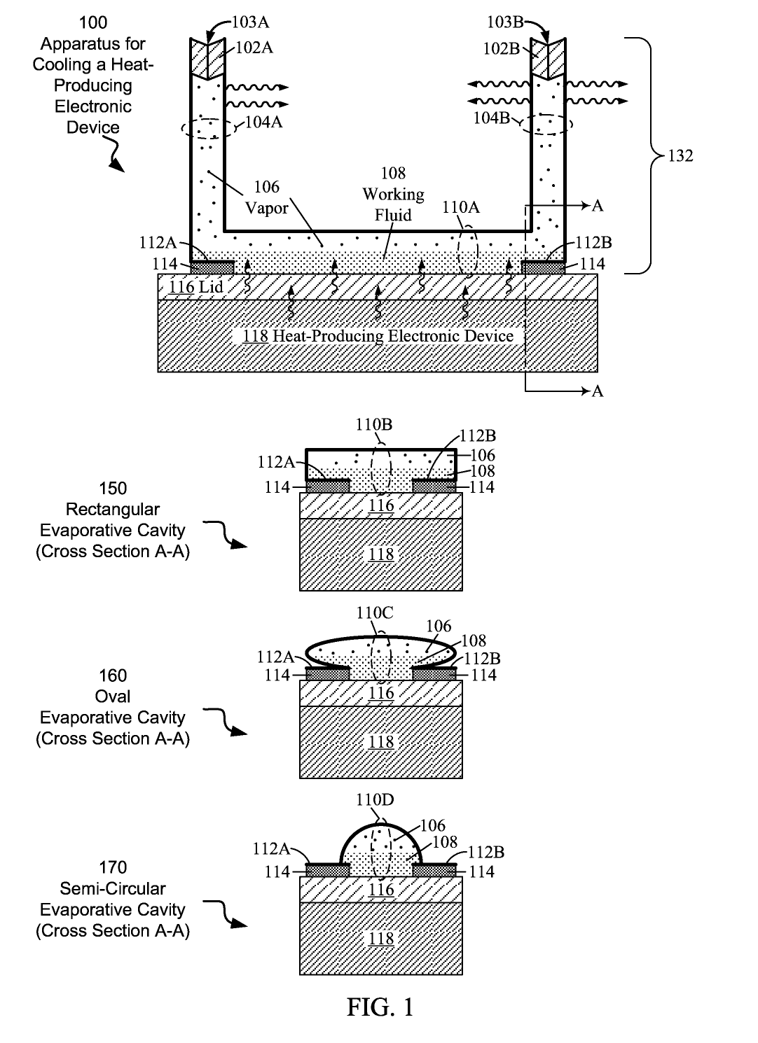

Certain embodiments relate to efficient transfer of heat from a heat-producing electronic device to a working fluid contained within a heat pipe apparatus. FIG. 1 includes four cross-sectional drawings 100, 150, 160 and 170 depicting an apparatus for cooling a heat-producing electronic device, according to embodiments of the present disclosure. The apparatus may include a thermally conductive vessel 132 mated with a lid 116 of a heat producing electronic device 118, according to embodiments of the present disclosure. In embodiments, the thermally conductive vessel 132 may contain a working fluid 108 in direct contact with the lid 116 of the heat-producing electronic device 118, which may be useful in creating an efficient heat transfer path from the heat producing electronic device 118 to the working fluid 108.

The thermally conductive vessel 132 may have an evaporative cavity 110A, at least one condensing cavity 104A, 104 B sealed by access ports 102A, 102B, respectively, and sealing surfaces 112A, 112B. Sealing layer 114 may be useful, when placed between sealing surfaces 112A, 112B and the top surface of lid 116, to create a hermetic seal which may contain the working fluid 108 in, and which may prevent a loss of vacuum from, thermally conductive vessel 132. The sealing layer 114 may include a thermal interface material (TIM), an O-ring, a gasket, or other material suitable for creating a hermetic seal. In certain embodiments, the thermally conductive vessel 132 may be constructed from metals such as copper and aluminum, or alloys containing copper or aluminum.

Sealing surfaces 112A, 112B may define an aperture in a bottom side of the thermally conductive vessel 132. The sealing surfaces 112A, 112B and the defined aperture may be configured to mate with, and be located inside a perimeter of, a top surface (e.g., lid 116) of the heat-producing electronic device 118, to form the evaporative cavity 110A. Evaporative cavity 110A may have a first wall that is the top surface of the heat-producing electronic device (e.g., lid 116) and a second wall that is an interior surface of the thermally conductive vessel 132.

The apparatus may also include at least one condensing cavity (e.g., 104A, 104B) adjoining the evaporative cavity 110A. During operation of the heat-producing electronic device, heat dissipated by the device 118 may vaporize a portion of the working fluid 108, contained within the evaporative cavity 110A, into vapor 106. The condensing cavities (e.g., 104A, 104B) may be used to receive at least a portion of the heat dissipated by the heat-producing electronic device by condensing vapor 106 into to a liquid state 108. Heat received by the condensing cavities (e.g., 104A, 104B) may be radiated and/or convectively dissipated from condensing cavity 104A, 104B into surrounding air.

The apparatus may also include at least one access port 102A, 102B which may each have a valve. The valves may be used, in an access mode, to allow the introduction and removal of working fluid 108 to the evaporative cavity 110A. The valve may also be used for the removal of non-condensable gases (NCG), such as oxygen or nitrogen, from the thermally conductive vessel 132. In a sealed mode, each valve may be used to hermetically seal its respective access port. The access ports may be useful in facilitating installation and removal of the thermally conductive vessel 132 from the heat producing electronic device 118 by providing a convenient pathway through which fluids and gases may be introduced to, and removed from, the thermally conductive vessel 132.

In certain embodiments, an access port valve may be, for example, a Schrader valve. In certain embodiments, an access port valve may be a section of elastomeric material having a self-sealing slot (e.g., 103A, 103B) or opening within it. An access port valve may be useful in allowing the connection of equipment such as a vacuum pump or a fluid insertion device to the thermally conductive vessel 132.

An evaporative cavity (e.g., 110A) may be constructed to have one of a variety of cross-sectional shapes. A certain cross-sectional shape may be chosen based upon an amount of exterior surface area the shape creates or a volume of working fluid (e.g., 108) that the shape maintains, in various orientations, in contact with the surface of the heat-producing electronic device 118. A particular cross-sectional shape may also be chosen based upon availability of materials and/or manufacturing processes used to construct it.

Views 150, 160 and 170 illustrate examples of three evaporative cavity cross-sectional shapes. A cross-sectional shape of an evaporative cavity may be chosen for a particular application based on dimensions of a heat-producing electronic device, a volume of working fluid (e.g., 108) to be contained, manufacturability and assembly constraints and other design criteria. A thermally conductive vessel 132 may be constructed through a variety of manufacturing processes such as casting and milling of metal shapes or bending and cold-rolling of metal stock. Processes for creating a thermally conductive vessel 132 may also include soldering, brazing, welding or the use of adhesives to assemble an evaporative cavity (e.g., 110A) to one or more condensing cavities (e.g., 104A, 104B).

View 150 depicts a cross-sectional view of an evaporative cavity 110B having a rectangular cross-sectional shape and sealing surfaces 112A, 112B, mated to lid 116 of heat producing electronic device 118. Evaporative cavity 110B is sealed by sealing layer 114, and contains working fluid 108 and vapor 106. The rectangular cross-sectional shape of evaporative cavity 110B may provide a relatively large exterior surface area, which may be useful in providing a supplemental area through which to dissipate heat. Evaporative cavity 110B may be relatively straightforward to form using traditional sheet-metal forming tools and techniques.

View 160 depicts a cross-sectional view of an evaporative cavity 110C having an oval cross-sectional shape and sealing surfaces 112A, 112B, mated to lid 116 of heat producing electronic device 118. Evaporative cavity 110C is sealed by sealing layer 114, and contains working fluid 108 and vapor 106. The oval cross-sectional shape of evaporative cavity 110C may provide a relatively large exterior surface area, which may be useful in providing a supplemental area through which to dissipate heat.

View 170 depicts a cross-sectional view of an evaporative cavity 110D having a semi-circular cross-sectional shape and sealing surfaces 112A, 112B, mated to lid 116 of heat producing electronic device 118. Evaporative cavity 110D is sealed by sealing layer 114, and contains working fluid 108 and vapor 106. The semi-circular cross-sectional shape of evaporative cavity 110D may be useful in providing relatively close containment of a working fluid (e.g., 108) in contact with the top surface of lid 116. The relatively small surface area of evaporative cavity 110D may be useful in minimizing the surface area of evaporative cavity 110D through which heat may be dissipated.

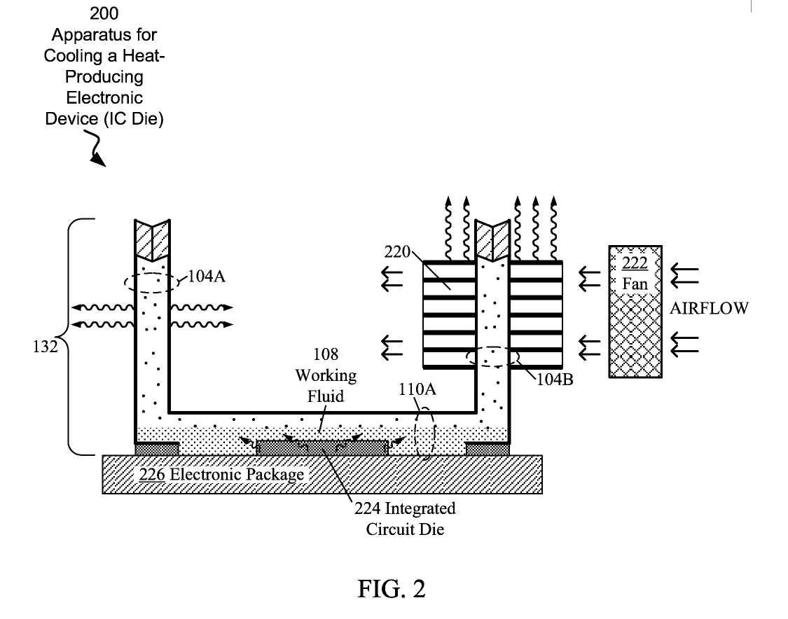

FIG. 2 is a cross-sectional drawing 200 depicting an apparatus for cooling a heat-producing integrated circuit (IC) die 224, according to embodiments consistent with FIG. 1. The apparatus may include a thermally conductive vessel 132 mated with an electronic package 226 that has IC die 224 mounted on a top side of the package 226, according to embodiments of the present disclosure. In embodiments, the thermally conductive vessel 132 may contain a working fluid 108 in direct contact with heat-producing IC die 224, which may be useful in creating an efficient heat transfer path from the IC die 224 to the working fluid 108. In certain embodiments, an efficient heat transfer path from IC die 224 to working fluid 108 may enable IC die 224 to be operated at increased frequencies, relative to embodiments including a lid (e.g., 116, FIG. 1). In certain embodiments, an efficient heat transfer path they enable IC die 224 to be operated at reduced temperatures, relative to embodiments including a lid (e.g., 116, FIG. 1).

The working fluid 108 may be chosen to be chemically compatible with electronic package 226 and IC die 224. For example, the working fluid 108 may be chosen to not dissolve or interact with material components of electronic package 226 such as fiberglass resins or organic materials. Working fluid 108 may be chosen to be electrically compatible with any electrical connections and/or circuits on electronic package 226 or IC die 224 which may be exposed to the working fluid 108. For example, working fluid 108 may be chosen in response to it possessing particular electrically insulative or dielectric properties.

The apparatus may also include a heat sink 220 thermally coupled to a condensing cavity 104B, which may be useful for increasing the heat dissipation capability of the apparatus. In certain embodiments, the heat sink 220 may be at a location remote to the evaporative cavity 110A. A fan 222 may be used to flow cooling air over the heat sink 220, which may be useful for increasing the heat dissipation capability of the apparatus. In certain embodiments, a fan 222 may be used to flow cooling air over a condensing cavity (e.g., 104A) which does not include attached heat sink.

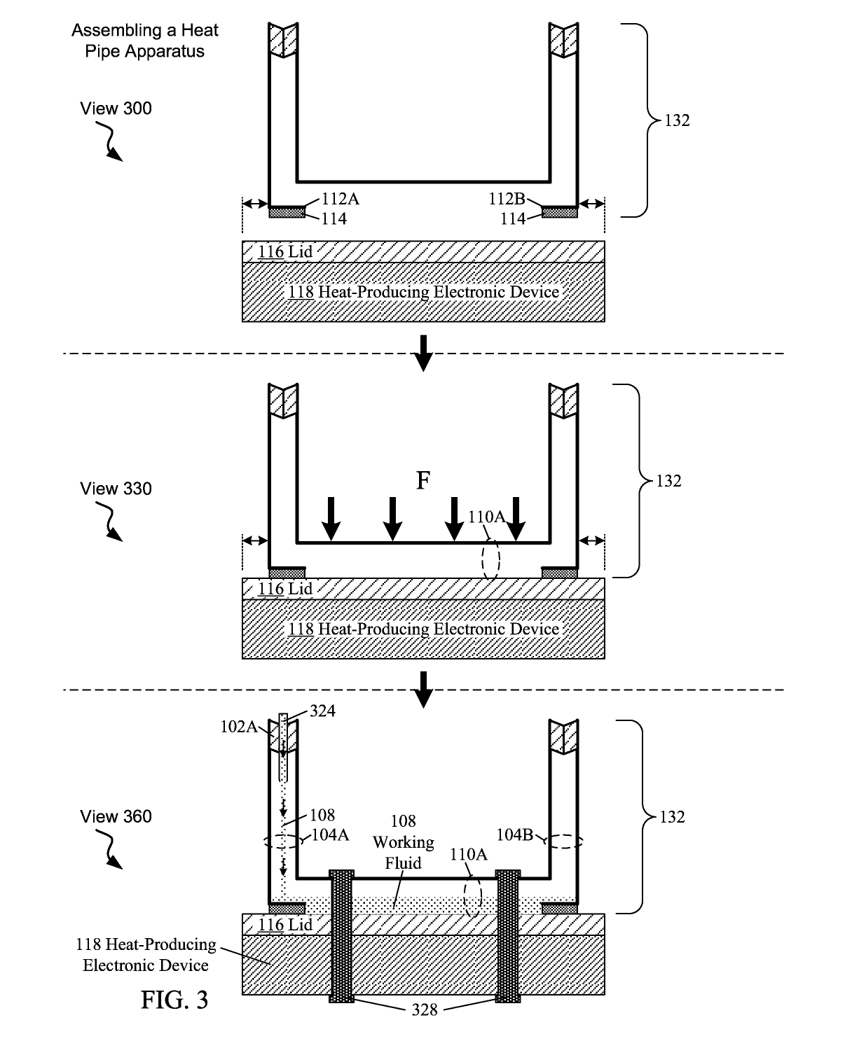

FIG. 3 includes three views 300, 330 and 360 depicting a sequence of steps for assembling a heat pipe apparatus configured to contain a working fluid 108 in contact with a heat-producing electronic device 118, according to embodiments consistent with the figures. The three views 300, 330 and 360 may be useful in illustrating details involved in creating a heat pipe apparatus assembly that has an efficient thermal path between a heat producing electronic device 118 and a working fluid 108. The views may be useful in illustrating details involved in creating a heat pipe apparatus that is hermetically sealed.

During the assembly steps depicted in the views 300, 330 and 360, precautions may be taken to ensure that working fluid 108 does not contact electrically sensitive components during an installation and/or removal of the thermally conductive vessel 132. The thermally conductive vessel 132 may be manufactured without working fluid 108, which may be introduced during the assembly process.

View 300 depicts the alignment of sealing surfaces 112A, 112B on a bottom side of a thermally conductive vessel 132 within a perimeter of a top surface (i.e., lid 116) of the heat-producing electronic device 118. Aligning the sealing surfaces 112A, 112B within a perimeter of a top surface of the heat-producing electronic device 118 may ensure that an evaporative cavity (110A, View 330) is created by the mating of the thermally conductive vessel 132 and the heat producing electronic device 118. A sealing layer 114 may be applied to the sealing surfaces 112A, 112B to create a hermetic seal between the thermally conductive vessel 132 and the heat producing electronic device 118. A hermetic seal may be useful in preventing loss of working fluid 108 and/or a loss of vacuum from the apparatus, once it is assembled. Sealing layer 114 may include materials such as a Shin-Etsu thermal grease, Bergquist gap pad, or an Indium TIM product.

View 330 depicts creating a hermetic seal by mating the sealing surfaces 112A, 112B of the thermally conductive vessel 132 with the top surface (i.e., lid 116) of the heat-producing electronic device 118. Mating the sealing surfaces 112A, 112B and the heat-producing electronic device 118 may create an evaporative cavity 110 A having a first wall that is the top surface of the heat-producing electronic device 118 and a second wall that is an interior surface of the thermally conductive vessel 132. A normal force “F” may be applied to the top of the thermally conductive vessel 132 to compress the sealing layer 114 to hermetically seal the evaporative cavity 110A and to hold the thermally conductive vessel to the heat-producing electronic device.

View 360 depicts maintaining the position of the thermally conductive vessel 132 relative to the lid 116 and introducing working fluid 108 into the evaporative cavity 110A, according to embodiments. Maintaining the position of the thermally conductive vessel 132 relative to the lid 116 may be useful for sustaining a hermetic seal between the thermally conductive vessel 132 and the lid 116 and ensuring proper function of the apparatus. In certain embodiments, at least a partial vacuum (reduced vapor and/or gas pressure) is maintained within the interior of the thermally conductive vessel 132 after it is mated to the heat-producing electronic device 118. A pressure differential between the interior of the thermally conductive vessel 132 and atmospheric pressure on the exterior of the vessel 132 may cause a force on the thermally conductive vessel 132 that is normal to the surface of the heat-producing electronic device 118, which in conjunction with friction between the sealing surfaces 112A, 112B, sealing layer 114, and the lid 116, may serve to hold the thermally conductive vessel 132 in a fixed position relative to the lid 116.

In certain embodiments, sealing layer 114 may be an adhesive TIM layer, which may serve to maintain the thermally conductive vessel 132 in a fixed position relative to lid 116. In certain embodiments, fastening devices such as attachment clips 328, clamps, screws or bolts may be useful in maintaining the thermally conductive vessel 132 in a fixed position relative to lid 116.

Working fluid 108 may be introduced, through access device 324 mated with access port 102A, into the hermetically sealed evaporative cavity 110A formed by mating the thermally conductive vessel 132 with the heat-producing electronic device 118. Introducing working fluid 108 into the hermetically sealed evaporative cavity 110A may be useful in containing the working fluid 108, and avoiding contact between the working fluid 108 and electronic devices.

The quantity of working fluid 108 that may be introduced into the evaporative cavity 110A may be sufficient to ensure a first portion of the working fluid is in a liquid state, and in contact with the lid 116, and that a second portion of the working fluid is in a vapor state, throughout an operational temperature range of the heat-producing electronic device 118. Ensuring that respective portions of the working fluid 108 are in a liquid and vapor states throughout the operational temperature range may ensure that the portion in a liquid state is present to receive dissipated heat from device 118, and that the portion in a vapor state is present to release the received heat by being condensed within at least one condensing cavity 104A, 104B.

Introducing the working fluid 108 into the evaporative cavity 110A may include the use of at least one access port, e.g., 102A. View 360 depicts an access device 324 inserted into access port 102A, through which working fluid 108 may be introduced into the evaporative cavity 110A. In certain embodiments, access device 324 may be connected to a syringe, tank or other container containing a working fluid 108. In certain embodiments, access port 102A may be a Schrader valve or other type of valve assembly, and access device 324 may include a mechanism to open and close the valve in conjunction with introducing working fluid 108 into the evaporative cavity 110A.

The use of access devices (e.g., 324) in combination with access ports (e.g., 102A) may be useful for introducing, without spillage, a measured quantity of working fluid 108 into an evaporative cavity (e.g., 110A), which may be useful in installation of a thermally conductive vessel (e.g., 132). Access devices in combination with access ports may be similarly used for draining working fluid prior to the removal of a thermally conductive vessel.

Non-condensing gas (NCG) pressure within a hermetically sealed thermally conductive vessel (e.g., 132) may interfere with the vaporization and condensing of a working fluid (e.g., 108), which may limit the efficiency of the heat pipe apparatus. NCGs may include gases found in air such as nitrogen, oxygen and carbon dioxide, which may not be condensed or transitioned to a liquid state over a normal operating temperature range of a heat pipe apparatus. Creation of an at least partial vacuum in, by removal of at least a portion of NCGs from, thermally conductive vessel (e.g., 132) containing a working fluid (e.g., 108) may be performed to enhance the working efficiency of a heat pipe apparatus.

The use of access devices (e.g., 324) in combination with access ports (e.g., 102A) may be useful for the removal of at least a portion of NCGs from a thermally conductive vessel. In certain embodiments, a vacuum pump may be attached to an access device 324 and to remove at least a portion of NCGs from thermally conductive vessel 132. In certain embodiments, a portion of the working fluid 108 may be at least partially vaporized, through heating, resulting in the vaporized working fluid 108 displacing at least a portion of the NCGs from thermally conductive vessel 132. Following the vaporizing of the working fluid 108, the heat pipe apparatus may be sealed and subsequently cooled, which may create the necessary internal pressure conditions for efficient heat pipe function. Certain embodiments may include the use of a vacuum pump in conjunction with vaporized working fluid 108.

Following the removal of at least a portion of NCGs from a thermally conductive vessel, the access device 324 may be removed from the access port 102A, and the access port 102A may be hermetically sealed, in order to preserve the at least partial vacuum within the thermally conductive vessel 132, and prevent leakage of (liquid or vaporized) working fluid 108.

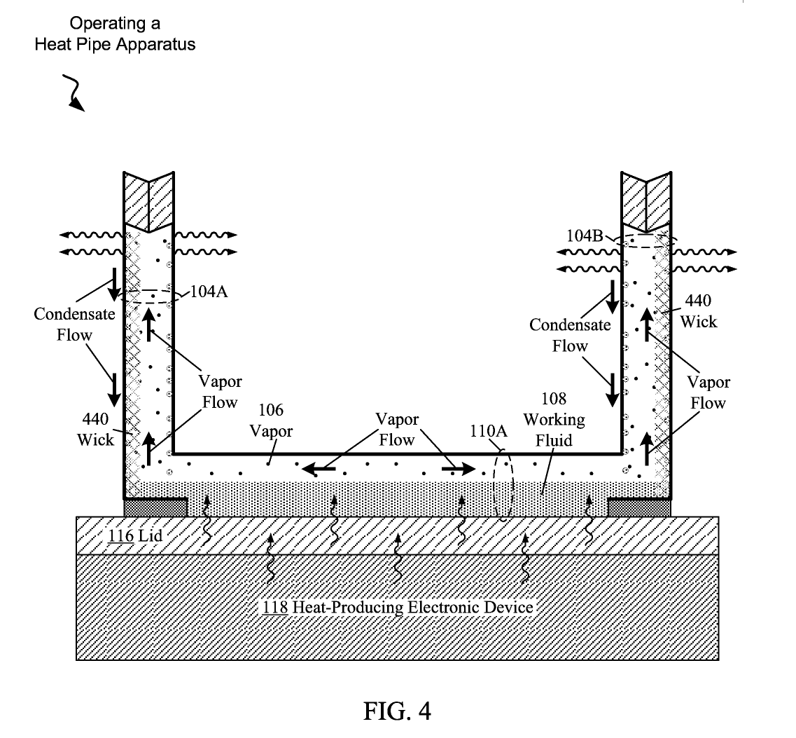

FIG. 4 depicts the cyclical operation of a heat pipe apparatus to remove heat from a heat-producing electronic device 118, according to embodiments consistent with the figures. FIG. 4 may be useful in illustrating various thermodynamic processes involved in the cyclical transferral (removal) of heat from a heat-producing electronic device to a remote location, which may include a condensing cavity and/or heat sink.

Working fluid 108 may receive heat that is dissipated from the heat-producing electronic device 118 when the device is being operated. In certain embodiments, heat may be transferred from the heat-producing electronic device 118 through lid 116 to the working fluid 108, and in certain embodiments, heat may be transferred directly from the heat-producing electronic device 118 to the working fluid 108 (see FIG. 2).

Heat received by working fluid 108 may vaporize a portion of working fluid 108, forming vapor 106. Working fluid 108 and vapor 106 may be contained within the hermetically sealed heat pipe apparatus, which may include evaporative cavity 110A and one or more adjoining condensing cavities 104A, 104B.

The heat received by working fluid 108 may be conducted by the flow of at least a portion of vapor 106 from evaporative cavity 110A to one or more adjoining condensing cavities 104A, 104B. Upon reaching the one or more adjoining condensing cavities 104A, 104B, at least a portion of the vapor 106 may be condensed into a liquid state (e.g., working fluid 108 condensate) in response to at least one surface of the one or more condensing cavities 104A, 104B having a temperature that is less than the temperature of the vapor 106. The condensation of the vapor 106 into droplets on at least one interior wall of the one or more adjoining condensing cavities 104A, 104B may release (transfer) heat from the vapor 106 to the one or more adjoining condensing cavities 104A, 104B. Heat released to the condensing cavities 104A, 104B may be dissipated into surrounding air and/or a heat sink or other thermally dissipative device (see FIG. 2).

In certain embodiments, one or more condensing cavities (e.g., 104A, 104B) may be located above, and have at least one interior surface that slopes downwards towards an evaporative cavity (e.g., 110A). In these embodiments, droplets of working fluid 108 condensate formed as a result of vapor 106 condensing on interior walls of condensing cavities 104A, 104B may begin to collect and flow towards the evaporative cavity 110A.

In certain embodiments, a vertical distance between one or more condensing cavities (e.g., 104A, 104B) and an adjoining evaporative cavity (e.g., 110A) may be insufficient to cause droplets of working fluid 108 condensate to flow towards the evaporative cavity 110A. In these embodiments, a wick 440 may be positioned between at least one of the condensing cavities (e.g., 104A, 104B) and the evaporative cavity, and may be used to draw working fluid 108 condensate from the condensing cavities (e.g., 104A, 104B) to the evaporative cavity 110A through capillary action. Inclusion of a wick within a heat pipe apparatus may be helpful in certain embodiments where gravity-induced condensate flow may be insufficient for heat pipe apparatus operation, as a result of a condensing cavity being at approximately the same elevation as an evaporative cavity.

A wick (e.g., 440), or wicking structure built into a top surface of an evaporative cavity (e.g., lid 116), may also be useful for distributing working fluid 108 across the top surface, which may be useful in applications where the orientation of lid 116 causes a first part of lid 116 to be below a second part of lid 116 (i.e., lid 116 is not level). In such applications, a wick (e.g., 440) or wicking structure located on the top surface of lid 116 may be useful for drawing working fluid 108 from the first (lower) part of lid 116 to the second (upper) part of lid 116. Distributing working fluid 108 across the top surface of lid 116 may be useful in increasing the heat dissipation capability of evaporative cavity 110A over a range of physical orientations.

A wick 440 may include a structure such as a metallic mesh having interstitial spaces between elements of the mesh that are small enough to leverage the effects of surface tension to promote capillary action between the wick and a working fluid. Other types of wick structures may include a grouping of small particles, metallic “fingers” or other structures featuring gaps between adjacent surfaces that promote surface tension and capillary action in a working fluid.

The process steps described may be continuously repeated to dispose of (dissipate) the heat generated by the heat-producing electronic component. Continuation of the described heat transfer cycle may depend upon several operational requirements, which may include the heat pipe apparatus continuing to receive heat from the heat-producing electronic device 118. Operational requirements may also include, maintaining a continuing temperature differential between at least one condensing cavity (e.g., 104A, 104B) and the evaporative cavity 110A, and maintaining a specified working fluid 108 volume and vapor pressure range. If any of the above described operational requirements are not met on a continuing basis, the heat transfer cycle may operate with limited efficiency or may cease.

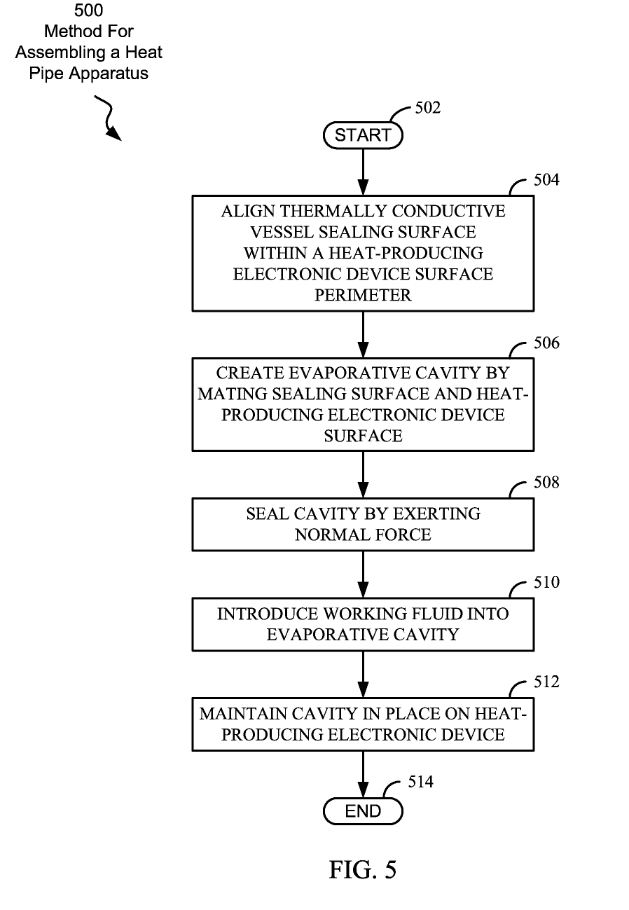

FIG. 5 is a flow diagram 500 illustrating of a method for assembling a heat pipe apparatus 500 having an evaporative cavity including at least one surface of a heat-producing electronic device, to cool the heat-producing electronic device, according to embodiments consistent with the figures. The method for assembling a heat pipe apparatus 500 may be useful for creating a heat pipe apparatus to efficiently transfer heat away from a heat-producing electronic device. The process 500 moves from start 502 to operation 504.

Operation 504 generally refers to the assembly operations that involve the alignment of sealing surfaces on the bottom side of a thermally conductive vessel within a heat-producing electronic device top surface perimeter, which may correspond to the view provided by 300 (FIG. 3) and its associated description. The alignment of sealing surfaces with respect to the heat-producing electronic device top surface perimeter may be in response to a particular thermal profile of the heat-producing electronic device surface. For example, in one application, a heat-producing electronic device may have a region from which the majority of its dissipated heat radiates. In certain embodiments, an aperture defined by the sealing surfaces of the thermally conductive vessel may be centered over the high heat dissipation region of the heat-producing electronic device surface. Once the sealing surfaces are aligned with the heat-producing electronic device surface perimeter, the process moves to operation 506.

Operation 506 generally refers to the assembly operations that involve creation of an evaporative cavity by the mating of sealing surfaces of the thermally conductive vessel with a surface of a heat-producing electronic device, which may correspond to the view provided by 330 (FIG. 3) and its associated description. During the process of mating the sealing surfaces to the electronic device surface, the alignment achieved by operation 504 is maintained. In certain embodiments, reference marks or measurements on the surface of the heat-producing electronic device may be useful in achieving a proper alignment during the process of mating. Once the evaporative cavity is created, the process moves to operation 508.

Operation 508 generally refers to the assembly operations that involve sealing of the evaporative cavity by exerting a normal force on the thermally conductive vessel, which may correspond to the view provided by 330 (FIG. 3) and its associated description. In certain embodiments, a fixture or jig may be used to apply the normal force to the thermally conductive vessel. The normal force may be calculated or determined to be sufficient to create an evaporative cavity (110A, FIG. 5) having a hermetic seal, while not causing deformation (bending or warping) of the thermally conductive vessel (132, FIG. 3) or its sealing surfaces. Once the evaporative cavity has been sealed, the process moves to operation 510.

Operation 510 generally refers to the assembly operations that involve introducing volume of working fluid into the evaporative cavity, which may correspond to the view provided by 360 (FIG. 3) and its associated description. The volume of working fluid introduced into the evaporative cavity may be calculated to ensure that the top surface of the heat-producing electronic device is covered by working fluid over a variety of ranges of heat pipe apparatus orientations and operating temperatures. In certain embodiments, for example, those involving cooling of integrated circuits, deionized (DI) water may be employed as working fluid. In certain embodiments, other liquids such as ammonia, ethanol or methanol may be suitable as a working fluid. Once working fluid has been introduced into the evaporative cavity, the process moves to operation 512.

Operation 512 generally refers to the assembly operations that involve maintaining the evaporative cavity in a fixed location relative to the surface of the heat-producing electronic device, which may correspond to the view provided by 360 (FIG. 3) and its associated description. In certain embodiments, maintaining the evaporative cavity in a fixed location may include the use of adhesives thermal interface materials (TIMs), possibly in conjunction with a vacuum within the heat pipe apparatus, and/or other types of fastening devices. Once the evaporative cavity is maintained in a fixed location relative to the heat-producing electronic device, the process 500 may end at block 514.

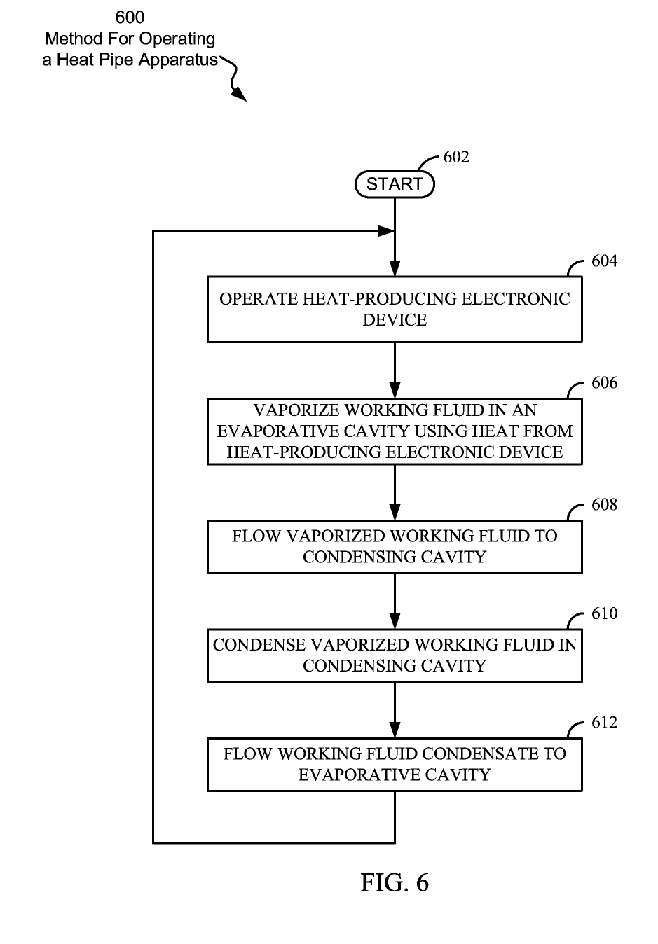

FIG. 6 is a flow diagram 600 illustrating of a method for operating a heat pipe apparatus 600, to remove heat from a heat-producing electronic device, according to embodiments consistent with the figures. The method for operating a heat pipe apparatus 600 may be useful for causing the heat pipe apparatus to efficiently transfer heat away from a heat-producing electronic device. A heat pipe apparatus may operate based on a temperature differential between an evaporative cavity and a condensing cavity. The process 600 moves from start 602 to operation 604.

Operation 604 generally refers to an operation that involves operating a heat-producing electronic device, which may correspond to the view provided by 400 (FIG. 4) and its associated description. Operating a heat-producing electronic device may include applying power to an IC or other electronic module or device that dissipates power in the form of heat, as a result of performing one or more designated functions. For example, certain microprocessors may dissipate over 100 W when active. Other heat-producing electronic devices may dissipate various amounts of heat, often from a relatively small surface area, resulting in relatively high heat densities. Once the heat-producing electronic device is operated, the process moves to operation 606.

Operation 606 generally refers to an operation that involves vaporizing, in response to heat received from the heat-producing electronic device, at least a portion of a working fluid (108 FIG. 4), which may correspond to the view provided by 400 (FIG. 4) and its associated description. The amount of heat required to vaporize (heat of vaporization) the working fluid may be significantly greater than the amount of heat that may be transferred through conductive or convective heat dissipation mechanisms. A relatively high heat of vaporization for a heat pipe apparatus working fluid may be useful in enabling the heat pipe to transfer relatively large amounts of heat from a heat-producing electronic device. Once the working fluid is at least partially vaporized, the process moves to operation 608.

Operation 608 generally refers to an operation that involves flowing vaporized working fluid to at least one condensing cavity, which may correspond to the view provided by 400 (FIG. 4) and its associated description. Evaporating working fluid may have a vapor pressure that is higher than a vapor pressure of a condensing or condensed working fluid, which may create, in certain embodiments, a pressure differential between an evaporative cavity and a condensing cavity. In certain embodiments, the vaporized working fluid may flow from an evaporative cavity to at least one condensing cavity in response to a pressure differential between the cavities. Once the vaporized working fluid has flowed to the at least one condensing cavity, the process moves to operation 610.

Operation 610 generally refers to an operation that involves condensing vaporized working fluid in at least one condensing cavity, which may correspond to the view provided by 400 (FIG. 4) and its associated description. In certain embodiments, the heat transfer capability of a heat pipe apparatus may be enhanced through the use of two or more condensing cavities adjoining the evaporative cavity. In certain embodiments, the heat transfer efficiency of a heat pipe apparatus may be increased by increasing the internal (condensing) surface area of the condensing cavity. The surface area may be increased through the use of fins or protrusions thermally attached to the interior wall of the condensing cavity. Once the vaporized working fluid is condensed in the at least one condensing cavity, the process moves to operation 612.

Operation 612 generally refers to an operation that involves flowing working fluid condensate to the evaporative cavity which may correspond to the view provided by 400 (FIG. 4) and its associated description. In certain embodiments, the use of a wick in the path of working fluid condensate flow between a condensing cavity and an evaporative cavity can allow working fluid condensate to flow without requiring the condensing cavity to be placed above the evaporative cavity. Once the working fluid condensate has been flowed to the evaporative cavity, the process returns to operation 604.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

What is claimed is:

1. An apparatus for cooling a heat-producing electronic device, comprising:
a thermally conductive vessel configured to, when mated with the heat-producing electronic device, contain a working fluid in contact with the heat-producing electronic device, the vessel having:
a sealing surface, on a bottom side of the thermally conductive vessel, that defines an aperture and that is configured to mate with an inside a perimeter of a top surface of the heat-producing electronic device;
a wall that is an interior surface of the thermally conductive vessel and that is configured to form an evaporative cavity when mated with the heat-producing electronic device, and
at least one condensing cavity adjoining the evaporative cavity and configured to, when the thermally conductive vessel is mated to the heat-producing electronic device, cool the working fluid by condensing the working fluid from a vapor state to a liquid state.

2. The apparatus of claim 1, further comprising at least one access port having a valve configured to:
in an access mode, allow introduction of working fluid to, and removal of working fluid and non-condensable gases from the thermally conductive vessel; and
in a sealed mode, hermetically seal the access port.

3. The apparatus of claim 1, further comprising a sealing layer, to form a hermetic seal between the sealing surface and the top surface of the heat-producing electronic device.

4. The apparatus of claim 3, wherein the sealing layer is at least one of a group consisting of: a thermal interface material (TIM), an O-ring, and a gasket.

5. The apparatus of claim 1, further comprising a working fluid, contained within the thermally conductive vessel, to conduct heat, received in the evaporative cavity and from the heat-producing electronic device, to the at least one condensing cavity.

6. The apparatus of claim 1, further comprising at least one of a group consisting of: a heat sink in thermally conductive contact with the at least one condensing cavity and a fan, configured to cool the condensing cavity.

7. The apparatus of claim 1, wherein the thermally conductive vessel includes metal.

8. The apparatus of claim 1, wherein the thermally conductive vessel includes at least one metal of a group of metals consisting of: copper and aluminum.

9. The apparatus of claim 1, wherein the thermally conductive vessel has a cross-sectional shape that is at least one shape of a group of shapes consisting of: semi-circular, rectangular and oval.

10. A method for assembling a heat pipe apparatus for cooling a heat-producing electronic device, the method comprising:
aligning a sealing surface on a bottom side of a thermally conductive vessel within a perimeter of a top surface of the heat-producing electronic device;
creating, by mating the sealing surface of the thermally conductive vessel with the top surface of the heat-producing electronic device, an evaporative cavity having a first wall that is the top surface of a heat-producing electronic device and a second wall that is an interior surface of the thermally conductive vessel;
sealing, by exerting a force normal to the top surface of the heat-producing electronic device to hold the thermally conductive vessel to the heat-producing electronic device, the evaporative cavity;
introducing, into the evaporative cavity, a quantity of working fluid to be in contact with and to cool, by receiving heat from, the top surface of the heat-producing electronic device.

11. The method of claim 10, wherein the sealing further comprises creating a hermetic seal by positioning a sealing layer between the sealing surface and the top surface of the heat-producing electronic device and within a perimeter of the top surface of a heat-producing electronic device.

12. The method of claim 10, wherein the quantity of working fluid introduced into the evaporative cavity is sufficient to ensure a first portion of the working fluid is in a liquid state and a second portion of the working fluid is in a vapor state throughout an operational temperature range of the heat-producing electronic device.

13. The method of claim 10, wherein introducing the quantity of working fluid includes use of at least one access port.

14. The method of claim 10, further comprising removing, through an access port, at least a portion of non-condensable gases (NCG) from within the thermally conductive vessel.

15. The method of claim 10, further comprising maintaining the thermally conductive vessel in a fixed position relative to the heat-producing electronic device by installing at least one fastening device of a group of fastening devices consisting of: a clip, a clamp, a screw and a bolt.

16. A method for operating a heat pipe apparatus to remove heat from a heat-producing electronic device, the method comprising:
vaporizing, using dissipated heat from the heat-producing electronic device, a portion of a working fluid contained within an evaporative cavity having a first wall that is a top surface of the heat-producing electronic device and a second wall that is an interior surface of a thermally conductive vessel;
flowing, in response to a vapor pressure differential between the evaporative cavity and a condensing cavity, a portion of vaporized working fluid to at least one condensing cavity of the thermally conductive vessel;
condensing, onto a surface of the condensing cavity, at least a portion of the vaporized working fluid, to transfer at least a portion of the dissipated heat to the condensing cavity and to form working fluid condensate;
flowing the working fluid condensate from the condensing cavity to the evaporative cavity of the thermally conductive vessel.

17. The method of claim 16, wherein flowing the working fluid condensate further comprises flowing the condensate through a wick positioned between the condensing cavity and the evaporative cavity.

18. The method of claim 16, wherein flowing the working fluid condensate further comprises flowing the working fluid condensate to an evaporative cavity that is located below the condensing cavity.

19. The method of claim 16, wherein vaporizing a portion of a working fluid further comprises vaporizing the fluid contained within an evaporative cavity having a first wall that is at least one of a group consisting of: a heat-producing integrated circuit (IC) and a lid in thermally conductive contact with a heat-producing IC.

20. The method of claim 16, wherein vaporizing a portion of a working fluid includes vaporizing deionized (DI) water.
